(19) United States
(12) Patent Application Publication
(10) Pub. No.: US 2025/0145814 A1
(43) Pub. Date: May 8, 2025

(54) FLUORORESIN COMPOSITION, FLUORORESIN FILM, LAMINATED FILM, AND METAL LAMINATED PLATE

(71) Applicant: Arisawa Mfg. Co., Ltd., Joetsu-Shi, Niigata (JP)

(72) Inventors: Akira Fujita, Niigata (JP); Kenji Nakamura, Niigata (JP); Hiroyuki Matsuyama, Niigata (JP)

(73) Assignee: Arisawa Mfg. Co., Ltd., Joetsu-Shi, Niigata (JP)

(21) Appl. No.: 18/835,901

(22) PCT Filed: Jan. 31, 2023
(86) PCT No.: PCT/JP2023/003070

§ 371 Date: Aug. 5, 2024

(30) Foreign Application Priority Data
Feb. 7, 2022 (JP) 2022-017427

(51) Int. Cl. C08L 27/18; B32B 15/082; B32B 27/08; B32B 27/28; B32B 27/30; C08F 214/26; C08G 73/10; C08K 3/36

(52) U.S. Cl. CPC C08L 27/18; B32B 15/082; B32B 27/08; B32B 27/281; B32B 27/304; C08F 214/262; C08G 73/1067; C08K 3/36; B32B 2311/12; B32B 2311/24; B32B 2311/30; B32B 2327/18; B32B 2379/08; B32B 2457/08; C08L 2203/16; C08L 2205/025; C08L 2205/035

(57) ABSTRACT

A fluororesin composition comprising: a fluororesin; a liquid crystal polymer resin; a polyimide resin; and an inorganic filler, wherein the polyimide resin has a water absorption rate of 1.0% by mass or less, the content of the fluororesin is 55% by mass or more with respect to the total amount of the fluororesin composition, the content of the polyimide resin is 0.5 to 5.0% by mass with respect to the total amount of the fluororesin composition, and the content of the inorganic filler is 18 to 67% by mass with respect to the content of the fluororesin.

### TECHNICAL FIELD

The present invention relates to a fluororesin composition, a fluororesin film, a laminated film, and a metal laminated plate.

### BACKGROUND ART

Polyimide resins are widely used as insulating materials for flexible printed circuit boards (FPCs). However, the demand for high speed communication in electronic equipment and high speed transmission (low transmission loss) associated with safety function improvement, such as installation of millimeter wave radars in automobiles, makes it difficult to meet this demand using only polyimide resins. It is known that this high speed transmission is affected by the dielectric constant and dissipation factor of insulating materials.

Therefore, fluororesins such as PTFE and liquid crystal polymers (LCPs) are attracting attention as insulating materials with excellent dielectric characteristics, but they have low adhesiveness with different materials such as metal foil. Furthermore, fluororesins are colorless and transparent when made into films, which poses a problem of poor UV laser processability when forming circuits and only allows for processing with CO₂ lasers.

Moreover, fluororesins have a large coefficient of linear thermal expansion (CTE) and pose a problem of dimensional stability, making it difficult to use them alone in the insulating layer of FPC materials. Rigid materials in which glass cloth is impregnated with fluororesins to impart dimensional stability are widely used. However, the use of glass cloth increases the product thickness and poses a problem of deteriorating the dielectric constant of insulating materials due to the glass.

As a means of solving such problems, the use of a laminated film of polyimide resin and fluororesin for the insulating layer of FPC materials has been investigated, and it has been confirmed that it improves the CTE. Although the UV laser processability can be improved by adding a coloring component to the fluororesin film, the dielectric characteristics of the insulating material are deteriorated due to the coloring component, and therefore, it cannot be said that both UV laser processability and dielectric characteristics have been achieved.

For example, Patent Literature 1 discloses a low dielectric polyimide substrate using a thermocompression bondable laminated polyimide film and a fluororesin film.

Also, Patent Literature 2 discloses a fluororesin film comprising tetrafluoroethylene-based polymer particles and a thermosetting polymer that is a polyimide resin precursor, a polyimide resin, a cyanate ester resin, or an epoxy resin.

Furthermore, Patent Literature 3 discloses that the CTE can be reduced by adding a thermosetting polyimide to a tetrafluoroethylene-based polymer, and that the UV laser processability can be improved by adding a functional compound containing a specific atom comprising titanium, silicon, magnesium, aluminum, cerium, and nitrogen.

### CITATION LIST

### Patent Literature

Patent Literature 1: Japanese Patent No. 4029732
Patent Literature 2: Japanese Patent Laid-Open No. 2020-37661
Patent Literature 3: Japanese Patent Laid-Open No. 2020-37662

### SUMMARY OF INVENTION

### Technical Problem

The low dielectric polyimide substrate of Patent Literature 1 does not absorb light in the UV region due to the use of fluororesin film, and poses a problem in that UV laser processing is difficult.

In addition, although the polyimide resin precursor and polyimide resin used for the thermosetting polymer in Patent Literature 2 have excellent heat resistance, their high water absorption rate and high dielectric characteristics (especially dissipation factor) are thought to deteriorate high speed transmission. Meanwhile, the cyanate ester resin and epoxy resin have a low water absorption rate, but pose a problem in that the heat resistance of the resins themselves is low.

Furthermore, the thermosetting polyimide resin of Patent Literature 3 has a high water absorption rate, which deteriorates dielectric characteristics (especially dissipation factor). Also, there is a description that liquid crystalline polyester can be added to the extent that the effects are not impaired, but there is no description of specific examples of addition.

That is, for these films and metal laminated plates using such films, in order to apply them to high speed communication and millimeter wave radar applications and to further improve circuit reliability, there is a demand to be excellent in the dissipation factor of the insulating material (hereinafter, also simply referred to as dissipation factor), adhesiveness with different materials such as metal foil (hereinafter, also simply referred to as adhesiveness), and coefficient of linear thermal expansion, and to have excellent UV laser processability that allows for the formation of fine through-holes.

The present invention has been made in view of such circumstances, and its object is to provide a fluororesin composition that can produce a metal laminated plate with excellent dissipation factor, adhesiveness, coefficient of linear thermal expansion, and UV laser processability, as well as a fluororesin film, a laminated film, and a metal laminated plate using the same.

### Solution to Problem

As a result of diligent investigations to solve the problems described above, the present inventors have found that the above problems can be solved by using a fluororesin composition comprising: a fluororesin; a liquid crystal polymer resin; a polyimide resin; and an inorganic filler, wherein the polyimide resin has a water absorption rate of 1.0% by mass or less, the content of the fluororesin is 55% by mass or more with respect to the total amount of the fluororesin composition, the content of the polyimide resin is 0.5 to 5.0% by mass with respect to the total amount of the fluororesin composition, and the content of the inorganic filler is 18 to 67% by mass with respect to the content of the fluororesin, thereby leading to the completion of the present invention.

That is, the present invention is as follows.

(1)

A fluororesin composition comprising:
a fluororesin;
a liquid crystal polymer resin;
a polyimide resin; and
an inorganic filler,
wherein the polyimide resin has a water absorption rate of 1.0% by mass or less,
a content of the fluororesin is 55% by mass or more with respect to a total amount of the fluororesin composition,
a content of the polyimide resin is 0.5 to 5.0% by mass with respect to a total amount of the fluororesin composition, and
a content of the inorganic filler is 18 to 67% by mass with respect to the content of the fluororesin.
   (2)

The fluororesin composition according to (1),
wherein a content of the liquid crystal polymer resin is 35% by mass or more with respect to a total amount of the liquid crystal polymer resin and the polyimide resin.
   (3)

The fluororesin composition according to (1) or (2),
wherein the polyimide resin is composed of a polyimide resin precursor resin obtained by allowing a diamine component to react with an acid dianhydride component,
the diamine component includes at least any of p-phenylenediamine, 1,3-bis(3-aminophenoxy)benzene, 1,4-bis(4-aminophenoxy)benzene, 2-(4-aminophenyl)benzoxazol-5-amine, and 1,3-bis(4-aminophenoxy)benzene, and
the acid dianhydride component includes at least any of p-phenylenebis(trimellitic acid monoester acid anhydride) and 3,3′,4,4′-biphenyltetracarboxylic dianhydride.
   (4)

The fluororesin composition according to any of (1) to (3),
wherein the inorganic filler includes a silica filler.
   (5)

The fluororesin composition according to (4),
wherein the inorganic filler further includes one or more selected from the group consisting of boron nitride and titanium oxide.
   (6)

The fluororesin composition according to any of (1) to (5),
wherein the fluororesin is selected from at least one or more of perfluoroalkoxyalkane and polytetrafluoroethylene.
   (7)

The fluororesin composition according to (6),
wherein the fluororesin includes perfluoroalkoxyalkane and polytetrafluoroethylene, and
a content of the perfluoroalkoxyalkane is 90% by mass or more with respect to a total amount of the fluororesin.
   (8)

A fluororesin film formed using the fluororesin composition according to any of (1) to (7).

(9)

A laminated film comprising:
a layer formed using the fluororesin composition according to any of (1) to (7); and
a layer formed using a non-thermoplastic resin,
wherein at least one of outermost layers is the layer formed using the fluororesin composition.
   (10)

The laminated film according to (9),
wherein a coefficient of linear thermal expansion of the non-thermoplastic resin is smaller than a coefficient of linear thermal expansion of the fluororesin composition.
   (11)

The laminated film according to (9) or (10),
wherein the non-thermoplastic resin is a polyimide resin.
   (12)

A metal laminated plate comprising:
the fluororesin film or laminated film according to any of (8) to (11); and
a metal foil.
   (13)

The metal laminated plate according to (12),
wherein the metal foil is any one selected from the group consisting of copper foil, copper alloy foil, stainless steel foil, and aluminum foil.
   (14)

The metal laminated plate according to (12) or (13),
wherein the metal foil has a surface roughness (Rz) of 1.5 μm or less on a surface in contact with the layer formed using the fluororesin composition or the layer formed using a non-thermoplastic resin.

### Advantageous Effects of Invention

According to the present invention, there can be provided a fluororesin composition that can produce a metal laminated plate with excellent dissipation factor, adhesiveness, coefficient of linear thermal expansion, and UV laser processability.

### DESCRIPTION OF EMBODIMENTS

Hereinafter, a form for implementing the present invention (hereinafter, referred to as “the present embodiment”) will be described in detail. Note that the present invention is not limited to the following embodiment, but can be implemented with various modifications within the scope of its gist.

### 1. Fluororesin Composition

A fluororesin composition according to the present invention is a fluororesin composition comprising: a fluororesin; a liquid crystal polymer resin; a polyimide resin; and an inorganic filler, wherein the polyimide resin has a water absorption rate of 1.0% by mass or less, the content of the fluororesin is 55% by mass or more with respect to the total amount of the fluororesin composition, the content of the polyimide resin is 0.5 to 5.0% by mass with respect to the total amount of the fluororesin composition, and the content of the inorganic filler is 18 to 67% by mass with respect to the content of the fluororesin. The fluororesin composition may also comprise other components as necessary.

When the fluororesin composition comprises a specific amount of fluororesin, the dissipation factor of a metal laminated plate obtained using it can be lowered, and when the fluororesin composition comprises a specific amount of liquid crystal polymer, the dissipation factor of a metal laminated plate obtained using it can be lowered and the adhesiveness can be improved. Also, when the fluororesin composition comprises a specific amount of polyimide resin, the UV laser processability can be improved without relatively compromising the adhesiveness of a metal laminated plate obtained using it, and when the fluororesin composition comprises a specific amount of inorganic filler, the coefficient of linear thermal expansion can be lowered without relatively compromising the adhesiveness of a metal laminated plate obtained using it. However, the relationship between the content and effects of each component is not limited to the above. Hereinafter, each of these components will be described in detail.

### 1.1. Fluororesin

The fluororesin of the present embodiment is not particularly limited as long as it is a fluorine-containing resin. Examples thereof include polymers that contain a monomer having a fluorine atom (hereinafter, referred to as “fluorine-containing monomer”) as a polymerization component. The fluororesin may be a homopolymer constituted by one polymerization component, or it may be a copolymer constituted by two or more polymerization components.

Examples of the fluorine-containing monomer include unsaturated fluorinated hydrocarbons (for example, fluoroolefins such as tetrafluoroethylene, hexafluoropropylene, and chlorotrifluoroethylene) and ether group-containing unsaturated fluorinated hydrocarbons (for example, fluorinated alkyl vinyl ethers). One of these fluorine-containing monomers may be used singly, or two or more of them may be used in combination.

Although the fluororesin is not particularly limited, examples thereof include perfluoroalkoxyalkane (PFA), polytetrafluoroethylene (PTFE), tetrafluoroethylene-hexafluoropropylene copolymer (FEP), polychlorotrifluoroethylene (PCTFE), chlorotrifluoroethylene-ethylene copolymer (ECTFE), and polyvinylidene fluoride (PVDF). One of these fluororesins may be used singly, or two or more of them may be used in combination.

Among these, the fluororesin is preferably selected from at least one or more of perfluoroalkoxyalkane (PFA) and polytetrafluoroethylene (PTFE), as they tend to be further excellent in dissipation factor. Also, it is more preferable that the fluororesin includes perfluoroalkoxyalkane (PFA) and polytetrafluoroethylene (PTFE) and that the content of the perfluoroalkoxyalkane (PFA) is 90% by mass or more with respect to the total amount of the fluororesin, and it is still more preferable that the content is 95% by mass or more.

As the fluororesin, a prepared product prepared by a known method may be used, or a commercially available product may be used.

The content of the fluororesin is 55% by mass or more with respect to the total amount of the fluororesin composition, preferably 55% by mass or more and 80% by mass or less, more preferably 65% by mass or more and 80% by mass or less, and still more preferably 70% by mass or more and 80% by mass or less. When the content of the fluororesin is 55% by mass or more with respect to the total amount of the fluororesin composition, there is a tendency that the dissipation factor can be lowered, and when the content of the fluororesin is 80% by mass or less with respect to the total amount of the fluororesin composition, there is a tendency that the above effects can be achieved to the extent that the effects of the present invention are not impaired.

### 1.2. Liquid Crystal Polymer Resin

The liquid crystal polymer (LCP) of the present embodiment is a thermoplastic polymer that forms an anisotropic molten phase, which means what is commonly referred to as a thermotropic liquid crystal polymer. Although such a liquid crystal polymer resin is not particularly limited, examples thereof include thermoplastic liquid crystal polyester (also referred to as thermotropic liquid crystal polyester) and thermoplastic liquid crystal polyesteramide (also referred to as thermotropic liquid crystal polyesteramide). Among them, in particular, the liquid crystal polymer resin preferably includes thermoplastic liquid crystal polyester from the viewpoint of dissipation factor and adhesiveness.

As such a liquid crystal polymer (LCP), a prepared product prepared by a known method may be used, or a commercially available product may be used.

Although the liquid crystal polymer that can be used in the present embodiment is not particularly limited, but specific examples thereof include “LAPEROS” manufactured by Polyplastics Co., Ltd., “VECTRA” manufactured by Celanese Corporation, “UENO LCP” manufactured by Ueno Fine Chemicals Industry, Ltd., “SUMIKASUPER LCP” manufactured by Sumitomo Chemical Co., Ltd., “XYDAR” manufactured by Solvay Specialty Polymers, “XYDAR” manufactured by ENEOS Corporation, and “Siveras” manufactured by Toray Industries, Inc.

The content of the liquid crystal polymer resin is preferably 35% by mass or more with respect to the total amount of the liquid crystal polymer resin and the polyimide resin, more preferably 35% by mass or more and 85% by mass or less, still more preferably 45% by mass or more and 75% by mass or less, and even more preferably 55% by mass or more and 65% by mass or less. When the content of the liquid crystal polymer resin is 35% by mass or more with respect to the total amount of the liquid crystal polymer resin and the polyimide resin, there is a tendency that the dissipation factor can be lowered and there is a tendency that the adhesiveness can be improved. Also, when the content of the liquid crystal polymer resin is 85% by mass or less with respect to the total amount of the liquid crystal polymer resin and the polyimide resin, there is a tendency that the above effects can be achieved to the extent that the effects of the present invention are not impaired.

### 1.3. Polyimide Resin

Although the polyimide resin of the present embodiment is not particularly limited as long as it has a water absorption rate of 1.0% by mass or less, examples thereof include thermoplastic polyimide resins and thermosetting polyimide resins. From the viewpoint of coefficient of linear thermal expansion, in particular, the polyimide resin is preferably a thermosetting polyimide resin. Although such a thermosetting polyimide resin is not particularly limited, examples thereof include condensation type polyimide resins obtained by copolymerizing an acid dianhydride and a diamine, bismaleimide resins, and maleimide resins. Among them, from the viewpoint of availability, heat resistance, and adhesiveness, the thermosetting polyimide resin is preferably a condensation type polyimide resin.

Note that, in the present embodiment, the “water absorption rate” means a water absorption rate measured by the following procedure.

The sample obtained by removing all of the copper foil from a two-layer flexible metal laminated plate composed of copper foil and polyimide resin by etching was dried under the conditions of 105° C. for 0.5 hours and subsequently cooled to room temperature, the mass of which was defined as the initial value (m0). After immersing the sample in pure water at 23° C. for 24 hours, its mass (md) was measured, and from the change in mass between the initial value and the mass after immersion, the water absorption rate under the treatment conditions D-24/23 (treatment in pure water at 23° C. for 24 hours) was measured using the following expression (1).

Water absorption rate (%)=(md−m0)×100/m0 (1)

Although the above two-layer flexible metal laminated plate is not particularly limited, for example, it may be fabricated as follows. The polyimide resin precursor obtained in Synthesis Example 1 described later is applied to a roughened surface of a low roughness copper foil using a bar coater so that the resin layer thickness after imidization is 12.5 μm, dried at 130° C. for 10 minutes, and after cooling the dried copper foil to which the polyimide resin precursor has been applied to room temperature, it is heated to 360° C. (object temperature) in stages, held at 360° C. for 2 hours, and then naturally cooled to room temperature.

Also, although the method for producing a polyimide resin with a water absorption rate of 1.0% by mass or less is not particularly limited, examples thereof include the methods described in Examples described later.

The polyimide resin is obtained through a polyimide resin precursor resin by curing and dehydration reactions, and the polyimide resin precursor resin is a resin obtained by allowing an acid dianhydride component to react with a diamine component. When comprising the polyimide resin, the light absorption in the UV region by the fluororesin composition is improved without compromising the adhesiveness with different materials, thus enabling UV laser processing. Furthermore, the interaction between the polyimide resin and the LCP resin in the fluororesin composition tends to improve the adhesiveness between the two components.

In the above, although the drying and curing conditions under which the polyimide resin precursor resin is cured and dehydrated to obtain the polyimide resin are not particularly limited, examples thereof include a heating temperature of 80 to 360° C. and a heating time of 1 to 30 minutes.

Although the acid dianhydride is not particularly limited, examples thereof include pyromellitic dianhydride, 2,3,6,7-naphthalenetetracarboxylic dianhydride, 3,3′,4,4′-biphenyltetracarboxylic dianhydride, 1,2,5,6-naphthalenetetracarboxylic dianhydride, 2,2′,3,3′-biphenyltetracarboxylic dianhydride, 3,3′,4,4′-benzophenonetetracarboxylic dianhydride, 4,4′-oxydiphthalic dianhydride, 2,2-bis(3,4-dicarboxyphenyl) propane dianhydride, 3,4,9,10-perylenetetracarboxylic dianhydride, bis(3,4-dicarboxyphenyl) propane dianhydride, 1,1-bis(2,3-dicarboxyphenyl) ethane dianhydride, 1,1-bis(3,4-dicarboxyphenyl) ethane dianhydride, bis(2,3-dicarboxyphenyl) methane dianhydride, bis(3,4-dicarboxyphenyl) ethane dianhydride, bis(3,4-dicarboxyphenyl) sulfone dianhydride, p-phenylenebis(trimellitic acid monoester acid anhydride), ethylenebis(trimellitic acid monoester acid anhydride), bisphenol A bis(trimellitic acid monoester acid anhydride), 2,2-bis(3,4-dicarboxyphenyl) hexafluoropropane dianhydride, and 2,2-bis(4-(3,4-dicarboxyphenoxy)phenyl) hexafluoropropane dianhydride. Among them, the acid dianhydride component preferably includes at least any of p-phenylenebis(trimellitic acid monoester acid anhydride) and 3,3′,4,4′-biphenyltetracarboxylic dianhydride. Thereby, there is a tendency that the water absorption rate of the polyimide resin is decreased and the dissipation factor of the fluororesin composition is further lowered.

One of these acid dianhydrides may be used singly, or two or more of them may be used in combination.

Although the diamine is not particularly limited, examples thereof include p-phenylenediamine, m-phenylenediamine, 2,4-diaminotoluene, 2,5-diaminotoluene, 2,4-diaminoxylene, 2,4-diaminodurene, 4,4′-diaminodiphenylmethane, 4,4′-methylenebis(2-methylaniline), 4,4′-methylenebis(2-ethylaniline), 4,4′-methylenebis(2,6-dimethylaniline), 4,4′-methylenebis(2,6-diethylaniline), 4,4′-diaminodiphenyl ether, 3,4′-diaminodiphenyl ether, 3,3′-diaminodiphenyl ether, 2,4′-diaminodiphenyl ether, 4,4′-diaminodiphenylsulfone, 3,3′-diaminodiphenylsulfone, 4,4′-diaminobenzophenone, 3,3′-diaminobenzophenone, 4,4′-diaminobenzanilide, benzidine, 3,3′-dihydroxybenzidine, 3,3′-dimethoxybenzidine, o-tolidine, m-tolidine, 2,2′-bis(trifluoromethyl)benzidine, 1,4-bis(4-aminophenoxy)benzene, 1,3-bis(4-aminophenoxy)benzene, 1,3-bis(3-aminophenoxy)benzene, 4,4′-bis(4-aminophenoxy) biphenyl, bis(4-(3-aminophenoxy)phenyl) sulfone, bis(4-(4-aminophenoxy)phenyl) sulfone, 2,2-bis(4-(4-aminophenoxy)phenyl) propane, 2,2-bis(4-(4-aminophenoxy)phenyl) hexafluoropropane, 2,2-bis(4-aminophenyl) hexafluoropropane, p-terphenylenediamine, 4,4′-methylenebis(cyclohexylamine), isophoronediamine, trans-1,4-diaminocyclohexane, cis-1,4-diaminocyclohexane, 1,4-cyclohexanebis(methylamine), 2,5-bis(aminomethyl) bicyclo[2.2.1]heptane, 2,6-bis(aminomethyl) bicyclo[2.2.1]heptane, 3,8-bis(aminomethyl)tricyclo[5.2.1.0]decane, 1,3-diaminoadamantane, 2,2-bis(4-aminocyclohexyl) propane, 2,2-bis(4-aminocyclohexyl) hexafluoropropane, 1,3-propanediamine, 1,4-tetramethylenediamine, 1,5-pentamethylenediamine, 1,6-hexamethylenediamine, 1,7-heptamethylenediamine, 1,8-octamethylenediamine, 1,9-nonamethylenediamine, and 2-(4-aminophenyl)benzoxazol-5-amine. Among them, the diamine component preferably includes at least any of p-phenylenediamine, 1,3-bis(3-aminophenoxy)benzene, 1,4-bis(4-aminophenoxy)benzene, 2-(4-aminophenyl)benzoxazol-5-amine, and 1,3-bis(4-aminophenoxy)benzene. Thereby, there is a tendency that the water absorption rate of the polyimide resin is decreased and the dissipation factor of the fluororesin composition is further lowered.

One of these diamines may be used singly, or two or more of them may be used in combination.

The content of the polyimide resin is 0.5 to 5.0% by mass with respect to the total amount of the fluororesin composition, preferably 1.0 to 4.0% by mass, and more preferably 2.0 to 3.0% by mass. When the content of the polyimide resin is 0.5% by mass or more with respect to the total amount of the fluororesin composition, there is a tendency that the UV laser processability can be improved, and when the content of the polyimide resin is 5.0% by mass or less with respect to the total amount of the fluororesin composition, there is a tendency that the adhesiveness in particular can be maintained to be high.

### 1.4. Inorganic Filler

Although the inorganic filler of the present embodiment is not particularly limited, examples thereof include silica, clay, talc, calcium carbonate, mica, diatomaceous earth, alumina, zinc oxide, titanium oxide, calcium oxide, magnesium oxide, iron oxide, tin oxide, antimony oxide, titanium oxide, calcium hydroxide, magnesium hydroxide, aluminum hydroxide, basic magnesium carbonate, magnesium carbonate, zinc carbonate, barium carbonate, dawsonite, hydrotalcite, calcium sulfate, barium sulfate, calcium silicate, montmorillonite, bentonite, activated clay, sepiolite, imogolite, sericite, glass fibers, glass beads, silica-based balloons, carbon black, carbon nanotubes, carbon nanohorns, graphite, carbon fibers, glass balloons, carbon balloons, wood powder, zinc borate, and boron nitride. Among the above, the inorganic filler preferably includes one or more selected from the group consisting of silica, boron nitride, and titanium oxide, more preferably includes silica, and still more preferably includes silica and further includes one or more selected from the group consisting of boron nitride and titanium oxide.

One of these inorganic fillers may be used singly, or two or more of them may be used in combination. Also, as the inorganic filler, a hollow filler may be used.

The content of the inorganic filler is 18 to 67% by mass with respect to the content of the fluororesin, preferably 20 to 50% by mass, and more preferably 20 to 40% by mass. It is still more preferably 20 to 33% by mass. When the content of the inorganic filler is 18% by mass or more with respect to the content of the fluororesin, there is a tendency that the coefficient of linear thermal expansion can be lowered, and when the content of the inorganic filler is 67% by mass or less with respect to the content of the fluororesin, there is a tendency that the adhesiveness can be maintained to be high.

### 1.5. Surfactant

To the fluororesin composition of the present embodiment, although not particularly limited, a surfactant may be added as other components, for example, to disperse the liquid crystal polymer resin and inorganic filler contained in the fluororesin composition well. Although the surfactant is not particularly limited, examples thereof include anionic, cationic, nonionic, and fluorine-based surfactants. In particular, fluorine-based surfactants are preferable from the viewpoint of dispersibility and miscibility. One of these surfactants may be used singly, or two or more of them may be used in combination. The surfactant is preferably 3 to 10% by mass with respect to the fluororesin, and more preferably 3 to 8% by mass.

### 2. Fluororesin Film

A fluororesin film in the present embodiment is a film formed using the fluororesin composition of the present embodiment. Such a fluororesin film can produce, although not particularly limited, a metal laminated plate with excellent dissipation factor by overlaying it on a circuit composed of a metal foil, such as copper foil, for example.

### 3. Laminated Film

A laminated film of the present embodiment comprises a layer formed using the fluororesin composition (hereinafter, also referred to as “fluororesin layer”) and a layer formed using a non-thermoplastic resin (hereinafter, also referred to as “non-thermoplastic resin layer”), and at least one of the outermost layers is the fluororesin layer described above. By comprising the above configuration, the fluororesin layer, which has excellent dissipation factor, can be in contact with the circuit, and high speed transmission characteristics tend to be excellent.

Also, in the case where circuits are formed on both sides of the laminated film, from the viewpoint of dissipation factor and high speed transmission characteristics, it is preferable that both of the outermost layers of the laminated film are the fluororesin layer.

Note that, in the laminated film of the present embodiment, the number of types of each resin layer of the fluororesin layer and the non-thermoplastic resin layer may be one, or may be two or more.

Although the resin used for the non-thermoplastic resin layer is not particularly limited, examples thereof include polyimide resin, polyamide resin, phenolic resin, and epoxy resin. Among them, the non-thermoplastic resin preferably includes polyimide resin, and is more preferably composed of polyimide resin. Thereby, there is a tendency that the laser processability is excellent when used for circuit materials, etc., and the conduction reliability by the plating treatment after laser processing is also excellent. One of the resins used for the non-thermoplastic resin layer may be used singly, or two or more of them may be used in combination.

As the polyimide resin that can be used for the non-thermoplastic resin layer, in addition to the above polyimide resins that may be contained in the fluororesin composition, a prepared product prepared by a known method, or a commercially available product may be used. Examples of the commercially available product include products from DU PONT-TORAY CO., LTD., the “Kapton EN Series”, “Kapton H Series”, and “Kapton V Series”, products from Kaneka Corporation, the “Apical HP Series” and “Apical NPI Series”, the “FS Series” manufactured by SKC Kolon PI, Inc., and a product from Ube Industries, Ltd., “Upilex S”.

The coefficient of linear thermal expansion of the non-thermoplastic resin is preferably smaller than the coefficient of linear thermal expansion of the fluororesin composition of the present embodiment. Thereby, even in the case where the fluororesin ratio is increased, the coefficient of linear thermal expansion of the laminated product can be kept low. Therefore, the laminated product tends to have improved dimensional stability due to the action of non-thermoplastic resin with a small coefficient of linear thermal expansion, while transmission loss can be kept low due to the action of fluororesin with excellent dielectric characteristics.

The non-thermoplastic resin preferably has a dielectric constant of 4.0 or less at 10 GHz, more preferably 3.8 or less, and still more preferably 3.6 or less. Also, the dissipation factor at 10 GHz is preferably 0.0050 or less, more preferably 0.0045 or less, and still more preferably 0.0040 or less. In particular, there is a tendency that the use of a non-thermoplastic resin with a small dissipation factor can reduce the transmission loss.

### 4. Metal Laminated Plate

A metal laminated plate (metal laminated product) of the present embodiment comprises the fluororesin film or laminated film of the present embodiment, and a metal foil. The metal laminated plate may have a form in which metal foils are each placed on both sides of the laminated film, or it may have a form in which a metal foil is placed on only one side of the laminated film.

Although the metal foil is not particularly limited, it is preferably any one or two or more selected from the group consisting of copper foil, copper alloy foil, stainless steel foil, and aluminum foil, for example, and more preferably copper foil.

Although the thickness of the metal foil is not particularly limited, in the case of a metal laminated plate as a circuit material, for example, it may be about 6 to 70 μm.

The metal foil may have a treated surface. For example, it may be subjected to an anti-corrosion treatment in order to prevent oxidation. It may also be subjected to a roughening treatment or a treatment with a silane coupling agent to enhance the adhesiveness of the laminated product.

In addition, the surface roughness (Rz) of the metal foil on the surface in contact with the layer formed using the fluororesin composition or the layer formed using a non-thermoplastic resin is preferably 1.5 μm or less, and more preferably 1.3 μm or less. When the surface roughness is 1.5 μm or less, the metal laminated plate tends to reduce the skin effect of the conductor of the circuit material when used as a circuit material, resulting in improved low transmission loss properties.

### 5. Method for Producing Metal Laminated Plate

As a method for producing the metal laminated plate of the present embodiment, known methods can be used and there are no particular limitations thereon, and examples thereof include a method in which a metal foil is overlaid on at least one of both sides of the laminated film of the present embodiment and press-laminated (hereinafter, also referred to as “press lamination method”). In the press lamination method, the pressurization temperature is not particularly limited and may be about 250 to 350° C., and the pressure is not particularly limited and may be about 3 to 5 MPa, for example.

Unless otherwise specified herein, the evaluation and measurement methods for each of the above-mentioned physical properties can be performed according to the methods described in the following Examples.

### EXAMPLES

Hereinafter, the present invention will be described further specifically with reference to Examples and Comparative Examples, but the present invention is not limited in any way to these Examples only.

### 1. Materials

The materials used in each of the Examples and Comparative Examples are as follows.

### (Fluororesin)

Perfluoroalkoxyalkane (PFA) (powder form):
   “Fulon+EA-2000” (powder form) manufactured by AGC Inc.
Perfluoroalkoxyalkane (PFA) (film form):
   “Fulon+EA-2000” (film form) with a thickness of 25 μm manufactured by AGC Inc.
Polytetrafluoroethylene (PTFE):
   “PTFE dispersion” manufactured by Mitsubishi Pencil Company, Limited

### (Polyimide Resin)

Fabricated by the methods described later.

### (LCP)

“XYDAR” manufactured by ENEOS Corporation

### (Inorganic Filler)

“FB-3SDC” manufactured by Denka Company Limited

### (Surfactant)

“Ftergent 710FL” manufactured by Neos Company Limited

### (Metal Foil)

Copper foil (product from Fukuda Metal Foil & Powder Co., Ltd., “CF-T49A-DS-HD2-12 μm”. Hereinafter, also referred to as “low roughness copper foil”) (Non-thermoplastic resin layer [polyimide film])
the FS series manufactured by SKC Kolon PI, Inc., thickness of 12.5 μm

### (Fluororesin Film)

“Fulon+EA-2000” (film form) with a thickness of 25 μm manufactured by AGC Inc.

### 2. Preparation of Polyimide Resin

### [Synthesis Example 1] PI-1 (low water absorption type: water absorption rate of 1.0% by mass or less)

In a reaction vessel, 68 g of N-methyl-2-pyrrolidone (NMP), 1.9563 g (0.01809 mol) of p-phenylenediamine (p-PDA), and 0.8609 g (0.00295 g) of 1,3-bis(4-aminophenoxy)benzene (TPE-R) were added, and the mixture was stirred at room temperature to dissolve p-PDA and TPE-R in NMP. To the resulting solution, 8.5710 g (0.01870 mol) of p-phenylenebis(trimellitic acid monoester acid anhydride) (TAHQ) and 0.6114 g (0.00208 mol) of 3,3′,4,4′-biphenyltetracarboxylic dianhydride (BPDA) were gradually added. Thereafter, by stirring the mixture at room temperature for 3 hours, a polyimide resin precursor PI-1 was obtained.

PI-1 was applied to the roughened surface of the low roughness copper foil using a bar coater so that the resin layer thickness after imidization was 12.5 μm, and dried at 130° C. for 10 minutes. After cooling the dried copper foil to which PI-1 had been applied to room temperature, it was heated to 360° C. (object temperature) in stages. After being held at 360° C. for 2 hours and then naturally cooled to room temperature, a two-layer flexible metal laminated plate composed of the copper foil and a polyimide layer was obtained.

A sample obtained by removing all of the copper foil from this two-layer flexible metal laminated plate by etching was dried under the conditions of 105° C. for 0.5 hours and subsequently cooled to room temperature, the mass of which was defined as the initial value (m0). After immersing the sample in pure water at 23° C. for 24 hours, its mass (md) was measured, and from the change in mass between the initial value and the mass after immersion, the water absorption rate under the treatment conditions D-24/23 was measured using the following expression (1). As a result, the water absorption rate was 0.76%.

Water absorption rate (%)=(md−m0)×100/m0 (1)

### [Synthesis Example 2] PI-2 (Normal Type: Water Absorption Rate of Larger than 1.0% by Mass)

In a reaction vessel, 68 g of NMP, 2.7991 g (0.02588 mol) of p-PDA, and 0.8408 g (0.00288 mol) of TPE-R were added, and the mixture was stirred at room temperature to dissolve p-PDA and TPE-R in NMP. To the resulting solution, 8.3602 g (0.02841 mol) of BPDA was gradually added. Thereafter, by stirring the mixture at room temperature for 3 hours, a polyimide resin precursor PI-2 was obtained.

PI-2 was applied to the roughened surface of the low roughness copper foil using a bar coater so that the resin layer thickness after imidization was 12.5 μm, and dried at 130° C. for 10 minutes. After cooling the dried copper foil to which PI-2 had been applied to room temperature, it was heated to 360° C. (object temperature) in stages. After being held at 360° C. for 2 hours and then naturally cooled to room temperature, a two-layer flexible metal laminated plate composed of the copper foil and a polyimide layer was obtained.

A sample obtained by removing all of the copper foil from this two-layer flexible metal laminated plate by etching was dried under the conditions of 105° C. for 0.5 hours and subsequently cooled to room temperature, the mass of which was defined as the initial value (m0). After immersing the sample in pure water at 23° C. for 24 hours, its mass (md) was measured, and from the change in mass between the initial value and the mass after immersion, the water absorption rate under the treatment conditions D-24/23 was measured using the above expression (1). As a result, the water absorption rate was 1.39%.

### 3. Fabrication of Metal Laminated Plate and Fluororesin Film

### Example 1

100 parts by mass of the above PFA (powder form), 2.5 parts by mass of the above LCP, 20 parts by mass of the polyimide resin precursor (PI-1) fabricated in Synthesis Example 1, 33 parts by mass of the above inorganic filler, and 5 parts by mass of the above surfactant were put into a mixing tank, and mixed and stirred at a temperature at which each component could be molten to obtain a fluororesin composition.

Thereafter, the fluororesin composition was applied to both sides of the above polyimide film having a thickness of 12.5 μm so that the thickness after drying was 25 μm, dried at 130° C. for 10 minutes, and then heated at 300° C. for 10 minutes to obtain a laminated film having fluororesin layers on both sides. A metal laminated plate in which the low roughness copper foil was placed on both sides of the laminated film was fabricated by overlaying them so that the two sides of the laminated film and the treated surface of the low roughness copper foil faced each other and press-laminating them for 10 minutes under the conditions of a temperature of 320° C. and a pressure of 4 MPa.

Subsequently, the fluororesin composition fabricated above was applied to the above low roughness copper foil so that the thickness after drying was 25 μm, dried at 130° C. for 10 minutes, and then heated at 300° C. for 10 minutes to obtain a copper foil with fluororesin having a fluororesin layer on one side. Thereafter, by removing all copper foil by etching, a fluororesin film was fabricated.

### Examples 2 to 9 and Comparative Examples 1 to 7

Metal laminated plates and fluororesin films of Examples 2 to 9 and Comparative Examples 1 to 7 were obtained by the same operations as in Example 1, except that the parts by mass of each component were changed according to Table 1 to Table 2.

### Example 10

The fluororesin composition obtained in Example 1 was applied to both sides of the above polyimide film having a thickness of 12.5 μm so that the thickness was 12.5 μm, dried at 130° C. for 10 minutes, and then heated at 300° C. for 10 minutes to obtain a laminated film having fluororesin layers on both sides. Furthermore, the fluororesin composition obtained in Example 1 was applied to the treated surface of the low roughness copper foil so that the thickness after drying was 12.5 μm, dried at 130° C. for 10 minutes, and then heated at 300° C. for 10 minutes to obtain a low roughness copper foil with fluororesin layer. By the same method, two sheets of the low roughness copper foil with fluororesin layer were fabricated in total. A metal laminated plate in which the low roughness copper foil was placed on both sides of the laminated film was fabricated by overlaying them so that the two sides of the laminated film and the fluororesin layer of the low roughness copper foil with fluororesin layer faced each other and press-laminating them for 10 minutes under the conditions of a temperature of 320° C. and a pressure of 4 MPa.

### Comparative Example 8

The low roughness copper foil, the fluororesin film (film form) with a thickness of 25 μm, the polyimide film with a thickness of 12.5 μm, the fluororesin film (film form) with a thickness of 25 μm, and the low roughness copper foil were overlaid in this order and press-laminated for 10 minutes under the conditions of a temperature of 320° C. and a pressure of 4 MPa, thereby fabricating a metal laminated plate in which the copper foil was placed on both sides of the laminated film.

### 3. Evaluation Methods

The measurement and evaluation of each physical property of the metal laminated plates obtained in Examples 2 to 10 and Comparative Examples 1 to 8 were performed by the following methods.

### <Dissipation Factor>

All of the copper foil of the metal laminated plate was removed by etching, which was then allowed to stand still under an atmosphere of 23° C. and 50% RH for 24 hours or longer. Thereafter, the dissipation factor was measured using “Network Analyzer N5230A manufactured by Agilent Technologies” under the conditions of a frequency of 10 GHz in accordance with the JPCA-DG03 SPDR method under an atmosphere of 23° C., and judged according to the following evaluation criteria.

### Evaluation Criteria

⊚: The dissipation factor is less than 0.002.
◯: The dissipation factor is 0.002 or more and less than 0.003.
x: The dissipation factor is 0.003 or more.

### <Adhesiveness>

The copper foil of the metal laminated plate was etched to form a circuit pattern with a width of 3 mm. The sample was allowed to stand still under an atmosphere of 23° C. and 50% RH for 24 hours or longer, whose peel strength was measured in accordance with JIS C6471, Section 8.1, with a peel direction of 90° and a tensile speed of 50 mm/min, and the adhesiveness was judged according to the following evaluation criteria.

### [Evaluation Criteria]

⊚: The adhesiveness is 10 N/cm or more.
◯: The adhesiveness is 7.0 N/cm or more and less than 10 N/cm.
x: The adhesiveness is less than 7.0 N/cm.

### <Coefficient of Linear Thermal Expansion>

Samples of the metal laminated plates with all of the copper foil removed by etching, the fluororesin films obtained in Examples 1 to 10 and Comparative Examples 1 to 7, and the fluororesin film (film form) used in Comparative Example 8 were allowed to stand still under an atmosphere of 23° C. and 50% RH for 24 hours or longer. Thereafter, setting the sample size to 5 mm in width and 15 mm in length, the coefficient of linear thermal expansion (CTE) in the MD direction was calculated from the dimensional change between 100° C. and 200° C. when heated at a load of 5 g and a temperature increase rate of 10° C./min using a thermomechanical analyzer TMA-60 manufactured by Shimadzu Corporation, and judged according to the following evaluation criteria.

### Evaluation Criteria

◯: The CTE of the sample of the metal laminated plate with all of the copper foil removed by etching is less than 30 [ppm/K], and the CTE of the fluororesin film is less than 130 [ppm/K].
x: The CTE of the sample of the metal laminated plate with all of the copper foil removed by etching is 30 [ppm/K] or more, and the CTE of the fluororesin film is 130 [ppm/K] or more.

### <UV Laser Processability>

The copper foil of the metal laminated plate was removed by etching to form a shape with a diameter of 100 μmφ, and drilling was performed using a laser processing machine LC-2K212 manufactured by Via Mechanics, Ltd. under the conditions of a frequency of 2000 Hz, an output of 11.5 W, and a pulse width of 18 μs. Thereafter, using a scanning microscope (hereinafter, also referred to as “SEM”) S-4800 manufactured by Hitachi High-Technologies Corporation, the bottom of the hole was observed under the conditions of an acceleration voltage of 20 kV, a magnification of 700 times, and an observation tilt angle of 10°. The UV laser processability was judged visually according to the following evaluation criteria.

### Evaluation Criteria

◯: No resin residue is present at the bottom of the hole.
x: There is a resin residue at the bottom of the hole.

The measurement and evaluation results of each physical property of the laminated film obtained in each of the Examples and Comparative Examples are shown in Table 1 and Table 2.

TABLE 1

| | | | Example | | | | | |
|---|---|---|---|---|---|---|---|---|
| | | Unit | 1 | 2 | 3 | 4 | 5 | 6 |
| Fluororesin | PFA | Parts by | 100 | 100 | 100 | 100 | 100 | 100 |
| | | mass | | | | | | |
| | PTFE | Parts by | 0 | 0 | 0 | 0 | 0 | 0 |
| | | mass | | | | | | |
| | PFA/fluororesin | % by mass | 100 | 100 | 100 | 100 | 100 | 100 |
| | Content of fluororesin/ | % by mass | 69 | 66 | 62 | 75 | 74 | 75 |
| | fluororesin composition | | | | | | | |
| Liquid | LCP | Parts by | 2.5 | 10 | 20 | 5 | 5 | 5 |
| crystal | | mass | | | | | | |
| polymer | Liquid crystal polymer/ | % by mass | 38 | 71 | 83 | 63 | 50 | 56 |
| | (liquid crystal polymer + | | | | | | | |
| | polyimide resin) | | | | | | | |
| Polyimide | PI-1 | Parts by | 4 | 4 | 4 | 3 | 5 | 4 |
| resin | | mass | | | | | | |
| | PI-2 | Parts by | 0 | 0 | 0 | 0 | 0 | 0 |
| | | mass | | | | | | |
| | Content of polyimide resin/ | % by mass | 2.8 | 2.6 | 2.5 | 2.3 | 3.7 | 3.0 |
| | fluororesin composition | | | | | | | |
| Inorganic | Silica | Parts by | 33 | 33 | 33 | 20 | 20 | 20 |
| filler | | mass | | | | | | |
| | Content of inorganic filler/ | % by mass | 33 | 33 | 33 | 20 | 20 | 20 |
| | content of fluororesin | | | | | | | |
| Surfactant | Fluorine-based surfactant | Parts by | 5 | 5 | 5 | 5 | 5 | 5 |
| | | mass | | | | | | |
| | Content of surfactant/ | % by mass | 5.0 | 5.0 | 5.0 | 5.0 | 5.0 | 5.0 |
| | content of fluororesin | | | | | | | |
| Dissipation | Judgment | — | ⊚ | ⊚ | ⊚ | ⊚ | ◯ | ◯ |
| factor | Measured value | — | 0.0018 | 0.0017 | 0.0017 | 0.0015 | 0.0022 | 0.0020 |
| Adhesiveness | Judgment | — | ◯ | ◯ | ◯ | ⊚ | ◯ | ⊚ |
| | Measured value | N/cm | 8.5 | 8.6 | 8.6 | 10.9 | 8.7 | 10.6 |
| Coefficient of | Judgment | — | ◯ | ◯ | ◯ | ◯ | ◯ | ◯ |
| linear thermal | Measured value (sample) | ppm/K | 19 | 18 | 17 | 21 | 20 | 20 |
| expansion | Measured value | ppm/K | 97 | 76 | 70 | 121 | 101 | 111 |
| (CTE) | (fluororesin film) | | | | | | | |
| UV laser | Judgment | — | ◯ | ◯ | ◯ | ◯ | ◯ | ◯ |
| processability | | | | | | | | |

| | | | Example | | | |
|---|---|---|---|---|---|---|
| | | Unit | 7 | 8 | 9 | 10 |
| Fluororesin | PFA | Parts by | 100 | 100 | 100 | 100 |
| | | mass | | | | |
| | PTFE | Parts by | 0 | 5 | 10 | 0 |
| | | mass | | | | |
| | PFA/fluororesin | % by mass | 100 | 95 | 91 | 100 |
| | Content of fluororesin/ | % by mass | 55 | 76 | 76 | 75 |
| | fluororesin composition | | | | | |
| Liquid | LCP | Parts by | 5 | 5 | 5 | 5 |
| crystal | | mass | | | | |
| polymer | Liquid crystal polymer/ | % by mass | 56 | 56 | 56 | 63 |
| | (liquid crystal polymer + | | | | | |
| | polyimide resin) | | | | | |
| Polyimide | PI-1 | Parts by | 4 | 4 | 4 | 3 |
| resin | | mass | | | | |
| | PI-2 | Parts by | 0 | 0 | 0 | 0 |
| | | mass | | | | |
| | Content of polyimide resin/ | % by mass | 2.2 | 2.9 | 2.8 | 2.3 |
| | fluororesin composition | | | | | |
| Inorganic | Silica | Parts by | 67 | 20 | 20 | 20 |
| filler | | mass | | | | |
| | Content of inorganic filler/ | % by mass | 67 | 19 | 18 | 20 |
| | content of fluororesin | | | | | |
| Surfactant | Fluorine-based surfactant | Parts by | 5 | 5 | 5 | 5 |
| | | mass | | | | |
| | Content of surfactant/ | % by mass | 5.0 | 4.8 | 4.5 | 5.0 |
| | content of fluororesin | | | | | |
| Dissipation | Judgment | — | ⊚ | ⊚ | ⊚ | ⊚ |
| factor | Measured value | — | 0.0019 | 0.0019 | 0.0018 | 0.0015 |
| Adhesiveness | Judgment | — | ◯ | ◯ | ◯ | ⊚ |
| | Measured value | N/cm | 8.1 | 9.1 | 7.6 | 13.0 |
| Coefficient of | Judgment | — | ◯ | ◯ | ◯ | ◯ |
| linear thermal | Measured value (sample) | ppm/K | 16 | 21 | 20 | 21 |
| expansion | Measured value | ppm/K | 60 | 113 | 117 | 121 |
| (CTE) | (fluororesin film) | | | | | |
| UV laser | Judgment | — | ◯ | ◯ | ◯ | ◯ |
| processability | | | | | | |

TABLE 2

| | | | Comparative Example | | | | | | | |
|---|---|---|---|---|---|---|---|---|---|---|
| | | Unit | 1 | 2 | 3 | 4 | 5 | 6 | 7 | 8 |
| Fluororesin | PFA | Parts by | 100 | 100 | 100 | 100 | 100 | 100 | 100 | 100 |
| | | mass | | | | | | | | |
| | PTFE | Parts by | 0 | 0 | 0 | 0 | 0 | 0 | 0 | 0 |
| | | mass | | | | | | | | |
| | PFA/fluororesin | % by mass | 100 | 100 | 100 | 100 | 100 | 100 | 100 | 100 |
| | Content of fluororesin/ | % by mass | 75 | 70 | 77 | 73 | 88 | 81 | 38 | — |
| | fluororesin composition | | | | | | | | | |
| Liquid | LCP | Parts by | 5 | 0 | 5 | 5 | 5 | 5 | 5 | 0 |
| crystal | | mass | | | | | | | | |
| polymer | Liquid crystal polymer/ | % by mass | 100 | 0 | 100 | 42 | 56 | 56 | 56 | — |
| | (liquid crystal polymer + | | | | | | | | | |
| | polyimide resin) | | | | | | | | | |
| Polyimide | PI-1 | Parts by | 0 | 4 | 0 | 7 | 4 | 4 | 4 | 0 |
| resin | | mass | | | | | | | | |
| | PI-2 | Parts by | 4 | 0 | 0 | 0 | 0 | 0 | 0 | 0 |
| | | mass | | | | | | | | |
| | Content of polyimide | % by mass | 3.0 | 2.8 | 0.0 | 5.1 | 3.5 | 3.2 | 1.5 | — |
| | resin/fluororesin | | | | | | | | | |
| | composition | | | | | | | | | |
| Inorganic | Silica | Parts by | 20 | 33 | 20 | 20 | 0 | 10 | 150 | 0 |
| filler | | mass | | | | | | | | |
| | Content of inorganic | % by mass | 20 | 33 | 20 | 20 | 0 | 10 | 150 | 0 |
| | filler/content of | | | | | | | | | |
| | fluororesin | | | | | | | | | |
| Surfactant | Fluorine-based surfactant | Parts by | 5 | 5 | 5 | 5 | 5 | 5 | 5 | 0 |
| | | mass | | | | | | | | |
| | Content of surfactant/ | % by mass | 5.0 | 5.0 | 5.0 | 5.0 | 5.0 | 5.0 | 5.0 | — |
| | content of fluororesin | | | | | | | | | |
| Dissipation | Judgment | — | X | ◯ | ⊚ | ◯ | ◯ | ◯ | ⊚ | ⊚ |
| factor | Measured value | — | 0.0032 | 0.0021 | 0.0010 | 0.0027 | 0.0022 | 0.0020 | 0.0012 | 0.0013 |
| Adhesiveness | Judgment | — | ◯ | X | ⊚ | X | ⊚ | ⊚ | X | ⊚ |
| | Measured value | N/cm | 8.7 | 6.8 | 12.0 | 6.8 | 12.0 | 11.1 | 6.0 | 12.0 |
| Coefficient of | Judgment | — | ◯ | ◯ | X | ◯ | X | X | ◯ | X |
| linear thermal | Measured value (sample) | ppm/K | 21 | 20 | 19 | 19 | 26 | 24 | 16 | 30 |
| expansion | Measured value | ppm/K | 113 | 129 | 130 | 120 | 145 | 140 | 54 | >200 |
| (CTE) | (fluororesin film) | | | | | | | | | |
| UV laser | Judgment | — | ◯ | ◯ | X | ◯ | ◯ | ◯ | ◯ | X |
| processability | | | | | | | | | | |

As shown in Table 1 and Table 2, according to the comparison between Examples 1 to 10 and Comparative Examples 1 to 8, it was found that the fluororesin compositions according to the present embodiment are superior in dissipation factor, adhesiveness, coefficient of linear thermal expansion, and UV laser processability compared to the fluororesin compositions according to Comparative Examples 1 to 8, which do not meet the configuration requirements of the fluororesin composition.

The present application is based on the Japanese Patent Application filed with Japanese Patent Office on Feb. 7, 2022 (Japanese Patent Application No. 2022-17427), and the content thereof is incorporated herein by reference.

1. A fluororesin composition comprising:
a fluororesin;
a liquid crystal polymer resin;
a polyimide resin; and
an inorganic filler,
wherein the polyimide resin has a water absorption rate of 1.0% by mass or less, a content of the fluororesin is 55% by mass or more with respect to a total amount of the fluororesin composition,
a content of the polyimide resin is 0.5 to 5.0% by mass with respect to a total amount of the fluororesin composition, and
a content of the inorganic filler is 18 to 67% by mass with respect to the content of the fluororesin.

2. The fluororesin composition according to claim 1,
wherein a content of the liquid crystal polymer resin is 35% by mass or more with respect to a total amount of the liquid crystal polymer resin and the polyimide resin.

3. The fluororesin composition according to claim 1,
wherein the polyimide resin is composed of a polyimide resin precursor resin obtained by allowing a diamine component to react with an acid dianhydride component,
the diamine component comprises at least any of p-phenylenediamine, 1,3-bis(3-aminophenoxy)benzene, 1,4-bis(4-aminophenoxy)benzene, 2-(4-aminophenyl)ben zoxazol-5-amine, and 1,3-bis(4-aminophenoxy)benzene, and
the acid dianhydride component comprises at least any of p-phenylenebis(trimellitic acid monoester acid anhydride) and 3,3′,4,4′-biphenyltetracarboxylic dianhydride.

4. The fluororesin composition according to claim 1, wherein the inorganic filler comprises silica.

5. The fluororesin composition according to claim 4,
wherein the inorganic filler further comprises one or more selected from the group consisting of boron nitride and titanium oxide.

6. The fluororesin composition according to claim 1,
wherein the fluororesin is selected from at least one or more of perfluoroalkoxyalkane and polytetrafluoroethylene.

7. The fluororesin composition according to claim 6,
wherein the fluororesin comprises perfluoroalkoxyalkane and polytetrafluoroethylene, and
a content of the perfluoroalkoxyalkane is 90% by mass or more with respect to the content of the fluororesin.

8. A fluororesin film formed using the fluororesin composition according to claim 1.

9. A laminated film comprising:
a layer formed using the fluororesin composition according to claim 1; and
a layer formed using a non-thermoplastic resin,
wherein at least one of outermost layers is the layer formed using the fluororesin composition.

10. The laminated film according to claim 9,
wherein a coefficient of linear thermal expansion of the non-thermoplastic resin is smaller than a coefficient of linear thermal expansion of the fluororesin composition.

11. The laminated film according to claim 9,
wherein the non-thermoplastic resin is a polyimide resin.

12. A metal laminated plate comprising:
the fluororesin film according to claim 8; and
a metal foil.

13. The metal laminated plate according to claim 12,
wherein the metal foil is any one selected from the group consisting of copper foil, copper alloy foil, stainless steel foil, and aluminum foil.

14. The metal laminated plate according to claim 12,
wherein the metal foil has a surface roughness (Rz) of 1.5 μm or less on a surface in contact with the layer formed using the fluororesin composition.

15. A metal laminate plate comprising:
the laminated film according to claim 9; and
a metal foil.

16. The metal laminated plate according to claim 15,
wherein the metal foil is any one selected from the group consisting of copper foil, copper alloy foil, stainless steel foil, and aluminum foil.

17. The metal laminated plate according to claim 15, wherein the metal foil has a surface roughness (Rz) of 1.5 μm or less on a surface in contact with the layer formed using the fluororesin composition or the layer formed using a non-thermoplastic resin.

18. The fluororesin composition according to claim 2,
wherein the polyimide resin is composed of a polyimide resin precursor resin obtained by allowing a diamine component to react with an acid dianhydride component,
the diamine component comprises at least any of p-phenylenediamine, 1,3-bis(3-aminophenoxy)benzene, 1,4-bis(4-aminophenoxy)benzene, 2-(4-aminophenyl)ben zoxazol-5-amine, and 1,3-bis(4-aminophenoxy)benzene, and
the acid dianhydride component comprises at least any of p-phenylenebis(trimellitic acid monoester acid anhydride) and 3,3′,4,4′-biphenyltetracarboxylic dianhydride.

19. The fluororesin composition according to claim 2, wherein the inorganic filler comprises silica.

20. The fluororesin composition according to claim 3, wherein the inorganic filler comprises silica.
